(19) United States
(12) Patent Application Publication
(10) Pub. No.: US 2025/0056987 A1
(43) Pub. Date: Feb. 13, 2025

(54) DISPLAY DEVICE

(71) Applicant: Sharp Display Technology Corporation, Kameyama City, Mie (JP)

(72) Inventor: Tamotsu SAKAI, Kameyama City, Mie (JP)

(21) Appl. No.: 18/721,878

(22) PCT Filed: Feb. 16, 2022
(86) PCT No.: PCT/JP2022/006090

§ 371 Date: Jun. 20, 2024

(51) Int. Cl. H10K 59/131; H10K 59/123

(52) U.S. Cl. CPC H10K 59/131; H10K 59/123

(57) ABSTRACT

A third TFT is provided with a third semiconductor layer in which a fifth conductor region, a sixth conductor region, and a third channel region are defined, and which is formed by a second semiconductor film made of an oxide semiconductor, with a fourth gate electrode provided on the third semiconductor layer via a fourth inorganic insulating film so as to overlap with the third channel region, and with a fifth gate electrode provided on a base substrate side of the third semiconductor layer via a second inorganic insulating film and a third inorganic insulating film so as to overlap with the third channel region.

### TECHNICAL FIELD

The disclosure relates to a display device.

### BACKGROUND ART

In recent years, as a display device replacing a liquid crystal display device, a self-luminous organic electroluminescence (hereinafter also referred to as “EL”) display device using an organic EL element has attracted attention. Here, for example, the organic EL element includes a first electrode (an anode electrode) provided on a flattening film of a thin film transistor (hereinafter, thin film transistor is also referred to as “TFT”) layer on which TFT layers are arrayed, an organic EL layer provided on the first electrode, and a second electrode (a cathode electrode) provided on the organic EL layer. In the organic EL display device, a plurality of the TFTs are provided for each of subpixels, which is the smallest unit of an image. Well known examples of a semiconductor layer constituting the TFT include a semiconductor layer made of polysilicon having high mobility, and a semiconductor layer made of an oxide semiconductor with a low leakage current such as In—Ga—Zn—O.

For example, PTL 1 discloses a display device having a hybrid structure in which a first TFT using a polysilicon semiconductor and a second TFT using an oxide semiconductor are respectively formed on a substrate.

### CITATION LIST

### Patent Literature

PTL 1: JP 2020-17558 A

### SUMMARY

### Technical Problem

Incidentally, in an organic EL display device in which seven of the TFTs, including a first initialization TFT, a threshold voltage compensation TFT, a write control TFT, a drive TFT, a power supply control TFT, a light emission control TFT, and a second initialization TFT, are provided for each of the subpixels, it has been proposed to use an oxide semiconductor for the first initialization TFT, the threshold voltage compensation TFT, and the second initialization TFT, and to use polysilicon for the write control TFT, the drive TFT, the power supply control TFT, and the light emission control TFT. Here, in order to improve the on/off characteristics of the TFT and also to shield light, the TFT using the oxide semiconductor often has a double gate structure including, for example, a semiconductor layer made of the oxide semiconductor, a lower gate electrode provided on the lower side of the semiconductor layer via a gate insulating film, and an upper gate electrode provided on the upper side of the semiconductor layer via another gate insulating film. When each of the lower gate electrodes of the first initialization TFT, the threshold voltage compensation TFT, and the second initialization TFT are formed of the same material in the same layer, the lower gate electrode of the second initialization TFT for resetting an electric charge accumulated in the anode electrode has a complicated configuration in terms of the layout of the wiring.

The disclosure has been made in view of the above point, and an object of the disclosure is to form a double gate structure TFT using an oxide semiconductor with as simple a configuration as possible.

### Solution to Problem

In order to achieve the above object, a display device according to the disclosure includes a display device including a base substrate, and a thin film transistor layer which is provided on the base substrate and in which a first semiconductor film made of polysilicon, a first inorganic insulating film, a first metal film, a second inorganic insulating film, a second metal film, a third inorganic insulating film, a second semiconductor film made of an oxide semiconductor, a fourth inorganic insulating film, and a third metal film are layered in this order. The thin film transistor layer includes, for each of subpixels constituting a display region, a first thin film transistor including a first semiconductor layer formed by the first semiconductor film, a second thin film transistor including a second semiconductor layer formed by the second semiconductor film, and a third thin film transistor including a third semiconductor layer formed by the second semiconductor film. The first thin film transistor includes the first semiconductor layer including a first conductor region and a second conductor region defined to be separated from each other, and also including a first channel region defined between the first conductor region and the second conductor region, and a first gate electrode provided overlapping the second channel region, on the first semiconductor layer, via the first inorganic insulating film, the first gate electrode being formed by the first metal film. The second thin film transistor includes the second semiconductor layer including a third conductor region and a fourth conductor region defined to be separated from each other, and also including a second channel region defined between the third conductor region and the fourth conductor region, a second gate electrode provided overlapping the second channel region, on the second semiconductor layer, via the fourth inorganic insulating film, the second gate electrode being formed by the third metal film, and a third gate electrode provided overlapping the second channel region, on a side of the base substrate of the second semiconductor layer, via the third inorganic insulating film, the third gate electrode being formed by the second metal film. The third thin film transistor includes the third semiconductor layer including a fifth conductor region and a sixth conductor region defined to be separated from each other, and also including a third channel region defined between the fifth conductor region and the sixth conductor region, a fourth gate electrode provided overlapping the third channel region, on the third semiconductor layer, via the fourth inorganic insulating film, the fourth gate electrode being formed by the third metal film, and a fifth gate electrode provided overlapping the third channel region, on a side of the base substrate of the third semiconductor layer, via the second inorganic insulating film and the third inorganic insulating film, the fifth gate electrode being formed by the first metal film.

### Advantageous Effects of Disclosure

According to the disclosure, a TFT having a double gate structure using an oxide semiconductor can be formed with as simple a configuration as possible.

### BRIEF DESCRIPTION OF DRAWINGS

FIG. 1 is a block diagram of an overall configuration of an organic EL display device according to a first embodiment of the disclosure.

FIG. 2 is an equivalent circuit diagram of a pixel circuit of the organic EL display device according to the first embodiment of the disclosure.

FIG. 3 is a plan view of a TFT layer constituting the organic EL display device according to the first embodiment of the disclosure.

FIG. 4 is a cross-sectional view of the organic EL display device according to the first embodiment of the disclosure.

FIG. 5 is a cross-sectional view schematically illustrating a layered structure of the TFT layer constituting the organic EL display device according to the first embodiment of the disclosure.

FIG. 6 is a timing chart for describing an operation of the pixel circuit of the organic EL display device according to the first embodiment of the disclosure.

### DESCRIPTION OF EMBODIMENTS

An embodiment according to the disclosure will be described in detail below with reference to the drawings. Note that the disclosure is not limited to the embodiment to be described below.

### First Embodiment

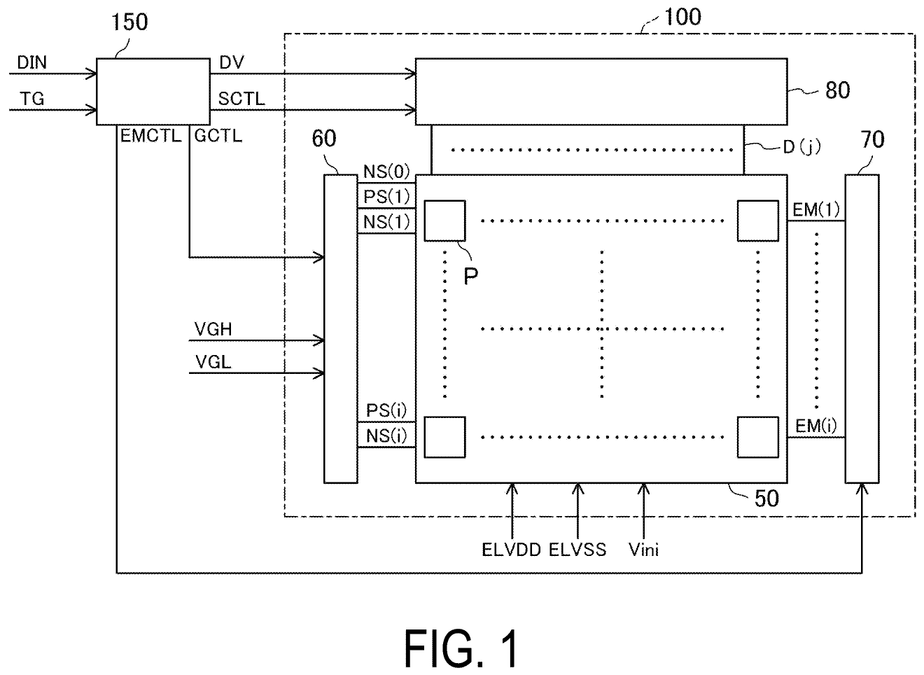

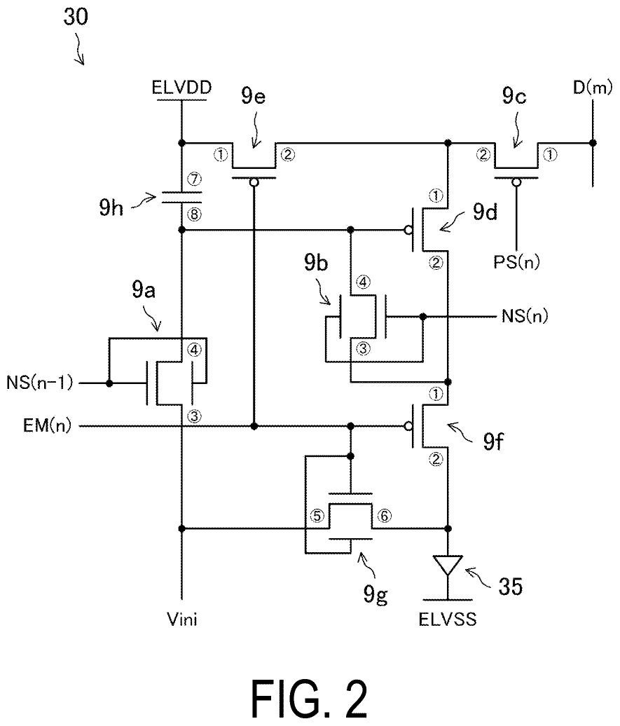

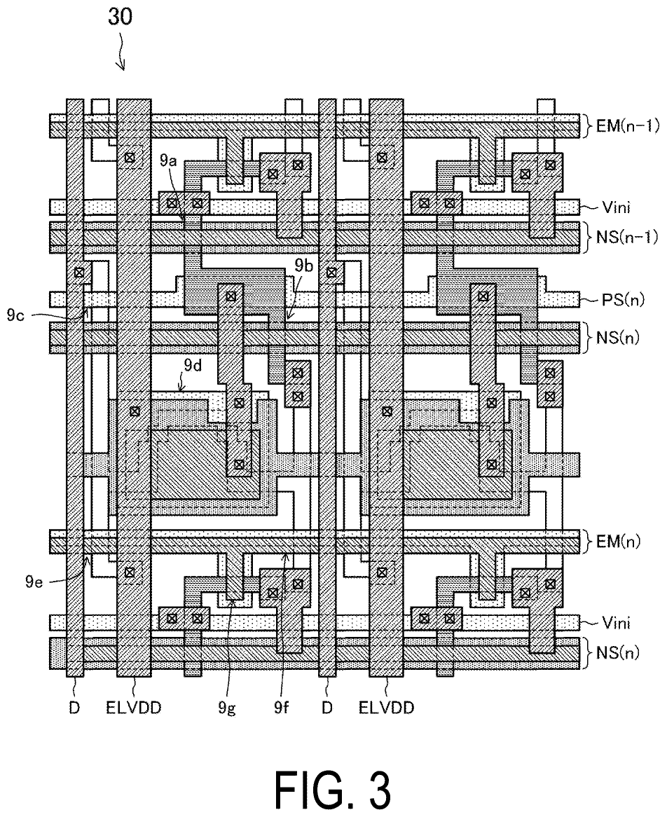

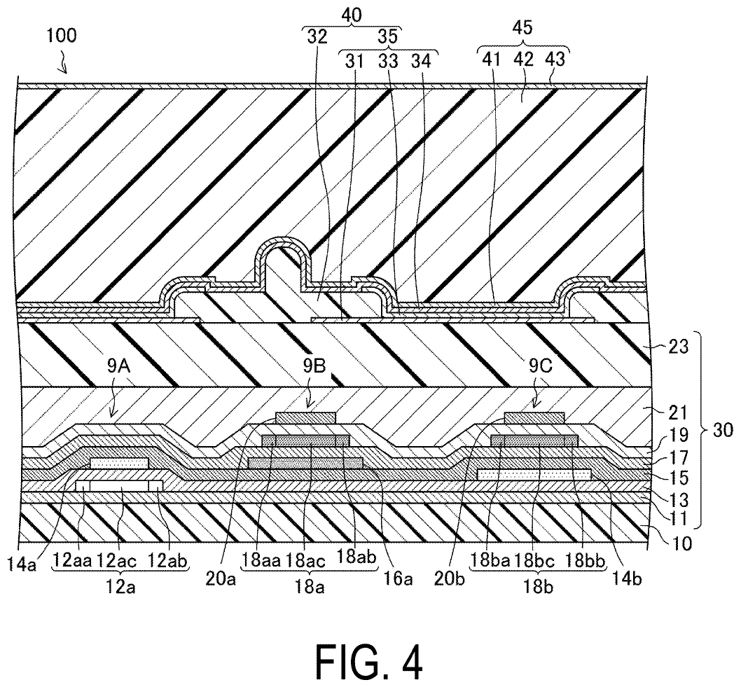

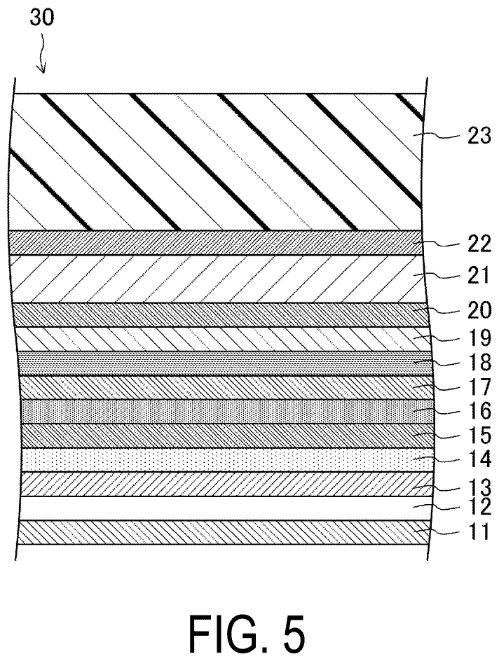

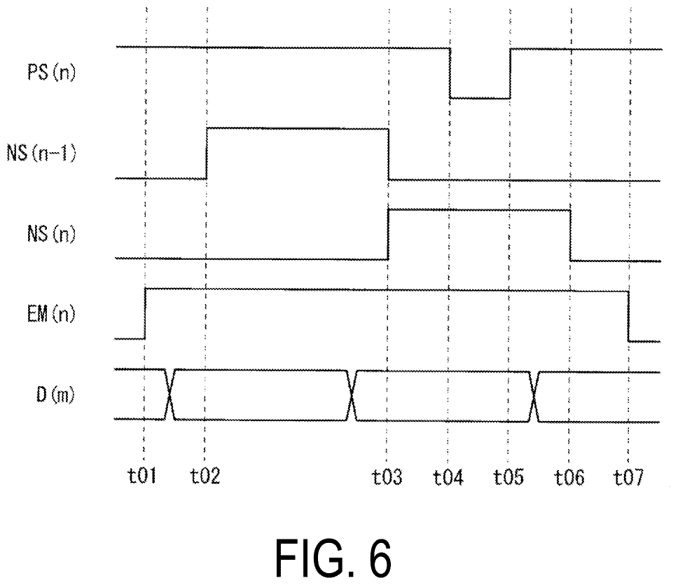

FIG. 1 to FIG. 6 illustrate a first embodiment of a display device according to the disclosure. Note that, in the following embodiment, an organic EL display device including an organic EL element layer is exemplified as the display device including a light-emitting element layer. Here, FIG. 1 is a block diagram of an overall configuration of an organic EL display device 100 according to the present embodiment. Further, FIG. 2 is an equivalent circuit diagram of a pixel circuit of a TFT layer 30 constituting the organic EL display device 100. Further, FIG. 3 is a plan view of the TFT layer 30 constituting the organic EL display device 100. Further, FIG. 4 is a cross-sectional view of the organic EL display device 100. Further, FIG. 5 is a cross-sectional view schematically illustrating a layered structure of the TFT layer 30. FIG. 6 is a timing chart for describing an operation of the pixel circuit of the organic EL display device 100. Note that, in the cross-sectional views of FIGS. 4 and 5, the same hatching as that in the plan view of FIG. 3 is used for components corresponding to those in the plan view of FIG. 3.

As illustrated in FIG. 1, the organic EL display device 100 is provided with a display region 50 in which a plurality of subpixels P are provided in a matrix shape, and a gate driver 60, an emission driver 70, and a source driver 80 provided in a frame region around the display region 50. Note that, as illustrated in FIG. 1, a display control circuit 150 that is electrically connected to the gate driver 60, the emission driver 70, and the source driver 80 is provided outside the organic EL display device 100.

Further, as illustrated in FIG. 4, the organic EL display device 100 includes a resin substrate 10 provided as a base substrate, the TFT layer 30 provided on the resin substrate 10, an organic EL element layer 40 provided as a light-emitting element layer on the TFT layer 30, and a sealing film 45 provided to cover the organic EL element layer 40.

The resin substrate 10 is formed of a polyimide resin or the like, for example.

As illustrated in FIG. 4, the TFT layer 30 includes a base coat film 11 provided on the resin substrate 10, four P-channel type first TFTs 9A, two N-channel type second TFTs 9B, one N-channel type third TFT 9C, and one capacitor 9h (see FIG. 2) provided on the base coat film 11 for each of the subpixels P, and a flattening film 23 provided on each of the first TFTs 9A, each of the second TFTs 9B, each of the third TFTs 9C, and each of the capacitors 9h. Further, as illustrated in FIG. 5, in the TFT layer 30, the base coat film 11, a first semiconductor film 12, a first gate insulating film 13, a first metal film 14, a second gate insulating film 15, a second metal film 16, a third gate insulating film 17, a second semiconductor film 18, a fourth gate insulating film 19, a third metal film 20, an interlayer insulating film 21, a fourth metal film 22, and the flattening film 23 are sequentially layered on the resin substrate 10. Here, the base coat film 11, the first gate insulating film 13 provided as a first inorganic insulating film, the second gate insulating film 15 provided as a second inorganic insulating film, the third gate insulating film 17 provided as a third inorganic insulating film, the fourth gate insulating film 19 provided as a fourth inorganic insulating film, and the interlayer insulating film 21 are each formed by, for example, a single-layer film of silicon nitride, silicon oxide or silicon oxynitride, or a layered film thereof. Note that, at least the third gate insulating film 17 and the fourth gate insulating film 19 on the side of a second semiconductor layer 18a and a third semiconductor layer 18b to be described below are each formed of a silicon oxide film. Further, the first semiconductor film 12 is made of polysilicon, and is, for example, a film for forming a first semiconductor layer 12a and the like to be described below. Further, the first metal film 14 is, for example, a film for forming a first gate electrode 14a, a fifth gate electrode 14b, and the like to be described below. The second metal film 16 is, for example, a film for forming a third gate electrode 16a and the like to be described below. Further, the second semiconductor film 18 is made of an oxide semiconductor, and is, for example, a film for forming the second semiconductor layer 18a, the third semiconductor layer 18b, and the like to be described below. Further, the third metal film 20 is, for example, a film for forming a second gate electrode 20a, a fourth gate electrode 20b, and the like to be described later. Further, the fourth metal film 22 is, for example, a film for forming data signal lines D, a high-level power supply line, a low-level power supply line, and the like to be described later.

As illustrated in FIG. 1, i first scanning signal lines PS(1) to PS(i), (i+1) second scanning signal lines NS(0) to NS(i), i light emission control lines EM(1) to EM(i), and j data signal lines D(1) to D(j) are provided in the display region 50 of the TFT layer 30. Note that each of i and j is an integer equal to or greater than 2, n is an integer in a range from 1 to i, and m is an integer in a range from 1 to j. Further, in FIG. 1, the first scanning signal lines PS, the second scanning signal lines NS, and the data signal lines D are not illustrated in the display region 50. Here, the first scanning signal lines PS(1) to PS(i) are signal lines for transmitting first scanning signals, which are control signals for the P-channel type TFTs. Further, the second scanning signal lines NS(0) to NS(i) are signal lines for transmitting second scanning signals, which are control signals for the N-channel type TFTs. Further, the light emission control lines EM(1) to EM(i) are signal lines for transmitting light emission control signals. Note that, as illustrated in FIG. 3, the first scanning signal lines PS(1) to PS(i), the second scanning signal lines NS(0) to NS(i), and the light emission control lines EM(1) to EM(i) are provided in parallel (side-by-side) with each other. Further, as illustrated in FIG. 3, the first scanning signal lines PS(1) to PS(i) and the data signal lines D(1) to D(j) are provided to be orthogonal to each other. Further, in the equivalent circuit diagram of FIG. 6 to be described below, the reference signs PS(1) to PS(i) are also assigned to the first scanning signals supplied to each of the first scanning signal lines PS(1) to PS(i), the reference signs NS(0) to NS(i) are also assigned to the second scanning signals supplied to each of the second scanning signal lines NS(0) to NS(i), the reference signs EM(1) to EM(i) are also assigned to the light emission control signals supplied to each of the light emission control lines EM(1) to EM(i), and the reference signs D(1) to D(j) are also assigned to data signals (data voltages) supplied to each of the data signal lines D(1) to D(j).

Furthermore, a power supply line (hereinafter, referred to as a “high-level power supply line”) that supplies a high-level power supply voltage ELVDD for driving an organic EL element 35 to be described later, a power supply line (hereinafter, referred to as a “low-level power supply line”) that supplies a low-level power supply voltage ELVSS for driving the organic EL element 35 and a power supply line (hereinafter, referred to as an “initialization power supply line”) that supplies an initialization voltage Vini are provided in the display region 50 of the TFT layer 30. Note that, in the present embodiment, as necessary, the reference sign ELVDD is also assigned to the high-level power supply line, the reference sign ELVSS is also assigned to the low-level power supply line, and the reference sign Vini is also assigned to the initialization power supply line. The high-level power supply voltage ELVDD, the low-level power supply voltage ELVSS, and the initialization voltage Vini are supplied from power supply circuits that are not illustrated.

As illustrated in FIG. 4, the first TFT 9A includes the first semiconductor layer 12a provided on the base coat film 11, and the first gate electrode 14a provided on the first semiconductor layer 12a with the first gate insulating film 13 interposed therebetween.

The first semiconductor layer 12a is formed of polysilicon, such as low temperature polysilicon (LTPS), for example, and, as illustrated in FIG. 4, includes a first conductor region 12aa and a second conductor region 12ab separated from each other, and a first channel region 12ac defined between the first conductor region 12aa and the second conductor region 12ab.

As illustrated in FIG. 4, the first gate electrode 14a is provided to overlap the first channel region 12ac of the first semiconductor layer 12a, and is configured to control conduction between the first conductor region 12aa and the second conductor region 12ab of the first semiconductor layer 12a.

Note that, as necessary, on the first TFT 9A, a first terminal electrode and a second terminal electrode are provided, which are formed on the interlayer insulating film 21 and are electrically connected to the first conductor region 12aa and the second conductor region 12ab of the first semiconductor layer 12a, respectively, via two contact holes formed in the layered film of the first gate insulating film 13, the second gate insulating film 15, the third gate insulating film 17, the fourth gate insulating film 19, and the interlayer insulating film 21.

As illustrated in FIG. 4, the second TFT 9B includes the second semiconductor layer 18a provided on the third gate insulating film 17, the second gate electrode 20a provided on the second semiconductor layer 18a via the fourth gate insulating film 19, and the third gate electrode 16a provided on the resin substrate 10 side of the second semiconductor layer 18a via the third gate insulating film 17.

For example, the second semiconductor layer 18a is formed of an oxide semiconductor, such as an In—Ga—Zn—O based semiconductor or the like, and, as illustrated in FIG. 4, and includes a third conductor region 18aa and a fourth conductor region 18ab separated from each other, and a second channel region 18ac defined between the third conductor region 18aa and the fourth conductor region 18ab. Here, the In—Ga—Zn—O based semiconductor is a ternary oxide of indium (In), gallium (Ga), and zinc (Zn), and a ratio (a composition ratio) of each of In, Ga, and Zn is not particularly limited. The In—Ga—Zn—O based semiconductor may be an amorphous semiconductor or may be a crystalline semiconductor. Note that a crystalline In—Ga—Zn—O based semiconductor in which a c-axis is oriented substantially perpendicular to a layer surface is preferable as the crystalline In—Ga—Zn—O based semiconductor. In place of the In—Ga—Zn—O based semiconductor, other oxide semiconductors may be included. Examples of the other oxide semiconductors may include an In—Sn—Zn—O based semiconductor (for example, In₂O₃—SnO₂—ZnO; InSnZnO). The In—Sn—Zn—O based semiconductor is a ternary oxide of indium (In), tin (Sn), and zinc (Zn). Alternatively, examples of the other oxide semiconductors may include an In—Al—Zn—O based semiconductor, an In—Al—Sn—Zn—O based semiconductor, a Zn—O based semiconductor, an In—Zn—O based semiconductor, a Zn—Ti—O based semiconductor, a Cd—Ge—O based semiconductor, a Cd—Pb—O based semiconductor, cadmium oxide (CdO), a Mg—Zn—O based semiconductor, an In—Ga—Sn—O based semiconductor, an In—Ga—O based semiconductor, a Zr—In—Zn—O based semiconductor, a Hf—In—Zn—O based semiconductor, an Al—Ga—Zn—O based semiconductor, a Ga—Zn—O based semiconductor, an In—Ga—Zn—Sn—O based semiconductor, InGaO₃(ZnO)₅, magnesium zinc oxide (MgₓZn₁₋ₓO), and cadmium zinc oxide (CdₓZn₁₋ₓO). Note that as the Zn—O based semiconductor, it is possible to use a semiconductor in a non-crystalline (amorphous) state of ZnO to which one kind or a plurality of kinds of impurity elements among group 1 elements, group 13 elements, group 14 elements, group 15 elements, group 17 elements, and the like are added, a semiconductor in a polycrystalline state, or in a microcrystalline state in which the non-crystalline state and the polycrystalline state are mixed, or a semiconductor to which no impurity element is added.

As illustrated in FIG. 4, the second gate electrode 20a is provided so as to overlap the second channel region 18ac of the second semiconductor layer 18a, and is configured to control conduction between the third conductor region 18aa and the fourth conductor region 18ab of the second semiconductor layer 18a.

As illustrated in FIG. 4, the third gate electrode 16a is provided so as to overlap the second channel region 18ac of the second semiconductor layer 18a, and is configured to control conduction between the third conductor region 18aa and the fourth conductor region 18ab of the second semiconductor layer 18a. Here, the third gate electrode 16a receives the same signal (the second scanning signal) as the second gate electrode 20a and also shields the second channel region 18ac of the second semiconductor layer 18a from light.

Note that, as necessary, on the second TFT 9B, a third terminal electrode and a fourth terminal electrode are provided, which are formed on the interlayer insulating film 21 and are electrically connected to the third conductor region 18aa and the fourth conductor region 18ab of the second semiconductor layer 18a, respectively, via two contact holes formed in the layered film of the fourth gate insulating film 19 and the interlayer insulating film 21.

As illustrated in FIG. 4, the third TFT 9C includes the third semiconductor layer 18b provided on the third gate insulating film 17, the fourth gate electrode 20b provided on the third semiconductor layer 18b via the fourth gate insulating film 19, and the fifth gate electrode 14b provided on the resin substrate 10 side of the third semiconductor layer 18b via the second gate insulating film 15 and the third gate insulating film 17. Here, in the third TFT 9C, the second gate insulating film 15 and the third gate insulating film 17 are disposed between the semiconductor layer (the third semiconductor layer 18b) and the lower gate electrode (the fifth gate electrode 14b), and in the second TFT 9B, the third gate insulating film 17 is disposed between the semiconductor layer (the second semiconductor layer 18a) and the lower gate electrode (the third gate electrode 16a). As a result, a thickness of the inorganic insulating film disposed between the semiconductor layer and the lower gate electrode is thicker in the third TFT 9C than in the second TFT 9B. Therefore, the drive capability of the third TFT 9C is lower than that of the second TFT 9B. However, since the third TFT 9C constitutes a second initialization TFT 9g (that does not need to be reset at a high speed) to be described later, there is no particular problem even when the drive capability is low. Further, since, as described below, the light emission control line EM disposed near the second initialization TFT 9g is constituted by a wiring line layer formed by the first metal film 14 and a wiring line layer formed by the third metal film 20, and does not include a wiring line layer formed by the second metal film 16, the electric capacitance of the light emission control line EM can be reduced, and as a result, the drive capability of the emission driver 70 can be set to be low.

In a similar manner to the second semiconductor layer 18a, the third semiconductor layer 18b is formed of an oxide semiconductor such as an In—Ga—Zn—O based semiconductor or the like, for example, and, as illustrated in FIG. 4, includes a fifth conductor region 18ba and a sixth conductor region 18bb separated from each other, and a third channel region 18bc defined between the fifth conductor region 18ba and the sixth conductor region 18bb.

As illustrated in FIG. 4, the fourth gate electrode 20b is provided so as to overlap the third channel region 18bc of the third semiconductor layer 18b, and is configured to control conduction between the fifth conductor region 18ba and the sixth conductor region 18bb of the third semiconductor layer 18b.

As illustrated in FIG. 4, the fifth gate electrode 14b is provided so as to overlap the third channel region 18bc of the third semiconductor layer 18b, and is configured to control conduction between the fifth conductor region 18ba and the sixth conductor region 18bb of the third semiconductor layer 18b. Here, the fifth gate electrode 14b receives the same signal (the second scanning signal) as the fourth gate electrode 20b, and also shields the third channel region 18bc of the third semiconductor layer 18b from light.

Note that, as necessary, on the third TFT 9C, a fifth terminal electrode and a sixth terminal electrode are provided, which are formed on the interlayer insulating film 21 and electrically connected to the fifth conductor region 18ba and the sixth conductor region 18bb of the third semiconductor layer 18b, respectively, via two contact holes formed in the layered film of the fourth gate insulating film 19 and the interlayer insulating film 21.

In the present embodiment, a write control TFT 9c, a drive TFT 9d, a power supply control TFT 9e, and a light emission control TFT 9f, which will be described below, are exemplified as the four P-channel type first TFTs 9A including the first semiconductor layer 12a formed of polysilicon, a first initialization TFT 9a and a threshold voltage compensation TFT 9b, which will be described below, are exemplified as the two N-channel type second TFTs 9B including the second semiconductor layer 18a formed of the oxide semiconductor, and a second initialization TFT 9g is exemplified as the one N-channel type third TFT 9C including the third semiconductor layer 18b formed of the oxide semiconductor (see FIG. 2). Note that, in the equivalent circuit diagram illustrated in FIG. 2, a first terminal electrode and a second terminal electrode of each of the TFTs 9c, 9d, 9e, and 9f are indicated by circled numbers 1 and 2, a third terminal electrode and a fourth terminal electrode of each of the TFTs 9a and 9b are indicated by circled numbers 3 and 4, a fifth terminal electrode and a sixth terminal electrode of the TFT 9g are indicated by circled numbers 5 and 6, and a first capacitance electrode and a second capacitance electrode of the capacitor 9h to be described later are indicated by circled numbers 7 and 8.

As illustrated in FIGS. 2 and 3, in the first initialization TFT 9a, a wiring line layer formed by the third metal film 20 of the second scanning signal line NS(n−1) of an (n−1)th row functions as the second gate electrode (20a), a wiring line layer formed by the second metal film 16 of the second scanning signal line NS(n−1) of the (n−1)th row functions as the third gate electrode (16a), the third terminal electrode of the first initialization TFT 9a is electrically connected to the initialization power supply line Vini, and the fourth terminal electrode of the first initialization TFT 9a is connected to the fourth terminal electrode of the threshold voltage compensation TFT 9b, the first gate electrode (14a) of the drive TFT 9d, and the second capacitance electrode of the capacitor 9h.

As illustrated in FIGS. 2 and 3, in the threshold voltage compensation TFT 9b, a wiring line layer formed by the third metal film 20 of the second scanning signal line NS(n) of an n-th row functions as the second gate electrode (20a), the wiring line layer formed by the second metal film 16 of the second scanning signal line NS(n) of the n-th row functions as the third gate electrode (16a), the third terminal electrode of the threshold voltage compensation TFT 9b is electrically connected to the second terminal electrode of the drive TFT 9d and the first terminal electrode of the light emission control TFT 9f, and the fourth terminal electrode of the threshold voltage compensation TFT 9b is electrically connected to the fourth terminal electrode of the first initialization TFT 9a, the first gate electrode (14a) of the drive TFT 9d, and the second capacitance electrode of the capacitor 9h.

As illustrated in FIGS. 2 and 3, in the write control TFT 9c, the first scanning signal line PS(n) of the n-th row functions as the first gate electrode (14a), the first terminal electrode of the write control TFT 9c is electrically connected to the data signal line D(m) of an m-th column, and the second terminal electrode of the write control TFT 9c is electrically connected to the first terminal electrode of the drive TFT 9d and the second terminal electrode of the power supply control TFT 9e.

As illustrated in FIGS. 2 and 3, the gate electrode (14a) of the drive TFT 9d is electrically connected to the fourth terminal electrode of the first initialization TFT 9a, the fourth terminal electrode of the threshold voltage compensation TFT 9b, and the second capacitance electrode of the capacitor 9h, the first terminal electrode of the drive TFT 9d is electrically connected to the second terminal electrode of the write control TFT 9c and the second terminal electrode of the power supply control TFT 9e, and the second terminal electrode of the drive TFT 9d is electrically connected to the third terminal electrode of the threshold voltage compensation TFT 9b and the first terminal electrode of the light emission control TFT 9f. Note that the high-level power supply voltage ELVDD is input to the first terminal electrode of the drive TFT 9d during a period in which the organic EL element 35 emits light, and the data signal D(m) is input to the first terminal of the drive TFT 9d during a period in which writing to the capacitor 9h is performed.

As illustrated in FIGS. 2 and 3, in the power supply control TFT 9e, the light emission control line EM(n) of the n-th row functions as the first gate electrode (14a), the first terminal electrode of the power supply control TFT 9e is electrically connected to the high-level power supply line ELVDD and the first capacitance electrode of the capacitor 9h, and the second terminal electrode of the power supply control TFT 9e is electrically connected to the second terminal electrode of the write control TFT 9c and the first terminal electrode of the drive TFT 9d. Note that, as illustrated in FIG. 3, the light emission control lines EM include a wiring line layer formed by the first metal film 14 and a wiring line layer formed by the third metal film 20.

As illustrated in FIGS. 2 and 3, in the light emission control TFT 9f, the light emission control line EM(n) of the n-th row functions as the first gate electrode (14a), the first terminal electrode of the light emission control TFT 9f is electrically connected to the third terminal electrode of the threshold voltage compensation TFT 9b and the second terminal electrode of the drive TFT 9d, and the second terminal electrode of the light emission control TFT 9f is electrically connected to the sixth terminal electrode of the second initialization TFT 9g and a first electrode 31 of the organic EL element 35 to be described later.

As illustrated in FIGS. 2 and 3, in the second initialization TFT 9g, the wiring line layer formed by the third metal film 20 of the light emission control line EM(n) of the n-th row functions as the fourth gate electrode (20b), the wiring line layer formed by the first metal film 14 of the light emission control line EM(n) of the n-th row functions as the fifth gate electrode (14b), the fifth terminal electrode of the second initialization TFT 9g is electrically connected to the initialization power supply line Vini, and the sixth terminal electrode of the second initialization TFT 9g is electrically connected to the second terminal electrode of the light emission control TFT 9f and the first electrode 31 of the organic EL element 35.

The capacitor 9h includes, for example, the first capacitance electrode formed by the second metal film 16, the second capacitance electrode formed by the first metal film 14, and the second gate insulating film 15 provided between the first capacitance electrode and the second capacitance electrode. Here, the first capacitance electrode of the capacitor 9h is electrically connected to the high-level power supply line ELVDD and the first terminal electrode of the power supply control TFT 9e, and the second capacitance electrode of the capacitor 9h is electrically connected to the fourth terminal electrode of the first initialization TFT 9a, the fourth terminal electrode of the threshold voltage compensation TFT 9b, and the first gate electrode (14a) of the drive TFT 9d. Note that, of the capacitors 9h, in addition to a first capacitor that includes the first capacitance electrode formed by the second metal film 16, the second capacitance electrode formed by the first metal film 14, and the second gate insulating film 15 provided between the first capacitance electrode and the second capacitance electrode, a second capacitor may be provided that includes a third capacitance electrode formed by the second metal film 16, a fourth capacitance electrode formed by the third metal film 20, and the third gate insulating film 17 provided between the third capacitance electrode and the fourth capacitance electrode.

The flattening film 23 has a flat surface in the display region 50, and is made of, for example, an organic resin material such as a polyimide resin or an acrylic resin, a polysiloxane-based spin on glass (SOG) material, or the like.

As illustrated in FIG. 4, the organic EL element layer 40 includes a plurality of the organic EL elements 35 provided as a plurality of light-emitting elements arrayed in a matrix shape in correspondence with the plurality of subpixels P, and an edge cover 32 provided in a lattice pattern shared by all the subpixels P in so as to cover peripheral end portions of the first electrode 31 of each of the organic EL elements 35.

As illustrated in FIG. 4, the organic EL element 35 includes, in each of the subpixels P, the first electrode 31 (anode electrode) provided on the flattening film 23 of the TFT layer 30, an organic EL layer 33 provided on the first electrode 31, and a second electrode 34 (cathode electrode) provided on the organic EL layer 33.

The first electrode 31 is electrically connected to the fourth terminal electrode of the light emission control TFT 9f of each of the subpixels P, via a contact hole formed in the flattening film 23. Further, the first electrode 31 has a function of injecting holes (positive holes) into the organic EL layer 33. Further, the first electrode 31 is preferably formed of a material having a large work function, in order to improve the hole injection efficiency into the organic EL layer 33. Here, examples of materials constituting the first electrode 31 include metal materials such as silver (Ag), aluminum (Al), vanadium (V), cobalt (Co), nickel (Ni), tungsten (W), gold (Au), titanium (Ti), ruthenium (Ru), manganese (Mn), indium (In), ytterbium (Yb), lithium fluoride (LiF), platinum (Pt), palladium (Pd), molybdenum (Mo), iridium (Ir), and tin (Sn). Further, examples of the materials constituting the first electrode 31 may include an alloy such as astatine (At)/astatine oxide (AtO2), or the like. Furthermore, examples of the materials constituting the first electrode 31 may include an electrically conductive oxide or the like, such as tin oxide (SnO), zinc oxide (ZnO), indium tin oxide (ITO), and indium zinc oxide (IZO). Further, the first electrode 31 may be formed by layering a plurality of layers made of any of the materials described above. Note that examples of compound materials having a high work function include indium tin oxide (ITO), indium zinc oxide (IZO), and the like.

The organic EL layer 33 includes a hole injection layer, a hole transport layer, a light-emitting layer, an electron transport layer, and an electron injection layer provided in order on the first electrode 31. Here, the hole injection layer is also referred to as an anode electrode buffer layer, and functions to reduce an energy level difference between the first electrode 31 and the organic EL layer 33 to thus improve the hole injection efficiency into the organic EL layer 33 from the first electrode 31. Note that examples of materials constituting the hole injection layer include triazole derivatives, oxadiazole derivatives, imidazole derivatives, polyarylalkane derivatives, pyrazoline derivatives, phenylenediamine derivatives, oxazole derivatives, styrylanthracene derivatives, fluorenone derivatives, hydrazone derivatives, stilbene derivatives, and the like. Further, the hole transport layer functions to improve the hole transport efficiency from the first electrode 31 to the organic EL layer 33. Note that examples of materials constituting the hole transport layer include porphyrin derivatives, aromatic tertiary amine compounds, styrylamine derivatives, polyvinyl carbazole, poly-p-phenylenevinylene, polysilane, triazole derivatives, oxadiazole derivatives, imidazole derivatives, polyarylalkane derivatives, pyrazoline derivatives, pyrazolone derivatives, phenylenediamine derivatives, arylamine derivatives, amino-substituted chalcone derivatives, oxazole derivatives, styrylanthracene derivatives, fluorenone derivatives, hydrazone derivatives, stilbene derivatives, hydrogenated amorphous silicon, hydrogenated amorphous silicon carbide, zinc sulfide, zinc selenide, and the like. Further, the light-emitting layer is a region where holes and electrons are injected from the first electrode 31 and the second electrode 34, respectively, and where the holes and the electrons recombine, when a voltage is applied by the first electrode 31 and the second electrode 34. Note that examples of materials constituting the light-emitting layer include metal oxinoid compounds (8-hydroxyquinoline metal complexes), naphthalene derivatives, anthracene derivatives, diphenylethylene derivatives, vinyl acetone derivatives, triphenylamine derivatives, butadiene derivatives, coumarin derivatives, benzoxazole derivatives, oxadiazole derivatives, oxazole derivatives, benzimidazole derivatives, thiadiazole derivatives, benzothiazole derivatives, styryl derivatives, styrylamine derivatives, bisstyrylbenzene derivatives, trisstyrylbenzene derivatives, perylene derivatives, perinone derivatives, aminopyrene derivatives, pyridine derivatives, rhodamine derivatives, aquidine derivatives, phenoxazone, quinacridone derivatives, rubrene, poly-p-phenylenevinylene, polysilane, and the like. Further, the electron transport layer functions to efficiently move the electrons to the light-emitting layer. Note that examples of materials constituting the electron transport layer include, as organic compounds, oxadiazole derivatives, triazole derivatives, benzoquinone derivatives, naphthoquinone derivatives, anthraquinone derivatives, tetracyanoanthraquinodimethane derivatives, diphenoquinone derivatives, fluorenone derivatives, silole derivatives, metal oxinoid compounds, and the like. Further, the electron injection layer functions to reduce an energy level difference between the second electrode 34 and the organic EL layer 33 to thus improve the electron injection efficiency into the organic EL layer 33 from the second electrode 34, and, due to this function, the drive voltage of the organic EL element 35 can be reduced. Note that examples of materials constituting the electron injection layer include inorganic alkali compounds, such as lithium fluoride (LiF), magnesium fluoride (MgF2), calcium fluoride (CaF2), strontium fluoride (SrF2), and barium fluoride (BaF2), aluminum oxide (Al2O3), strontium oxide (SrO), and the like.

As illustrated in FIG. 4, the second electrode 34 is provided in common to all of the subpixels P so as to cover each of the organic EL layers 33 and the edge cover 32. Further, the second electrode 34 functions to inject the electrons into the organic EL layer 33. Further, the second electrode 34 is preferably formed of a material having a low work function, in order to improve the electron injection efficiency into the organic EL layer 33. Further, as illustrated in FIG. 2, the second electrode 34 is electrically connected to the low-level power supply line ELVSS. Here, examples of materials constituting the second electrode 34 include silver (Ag), aluminum (Al), vanadium (V), calcium (Ca), titanium (Ti), yttrium (Y), sodium (Na), manganese (Mn), indium (In), magnesium (Mg), lithium (Li), ytterbium (Yb), lithium fluoride (LiF), and the like. Further, the second electrode 34 may be formed of an alloy, such as magnesium (Mg)/copper (Cu), magnesium (Mg)/silver (Ag), sodium (Na)/potassium (K), astatine (At)/astatine oxide (AtO2), lithium (Li)/aluminum (Al), lithium (Li)/calcium (Ca)/aluminum (Al), lithium fluoride (LiF)/calcium (Ca)/aluminum (Al) and the like. Further, the second electrode 34 may be formed of an electrically conductive oxide, such as tin oxide (SnO), zinc oxide (ZnO), indium tin oxide (ITO), and indium zinc oxide (IZO), and the like. Further, the second electrode 34 may be formed by layering a plurality of layers made of any of the materials described above. Note that examples of materials having a low work function include magnesium (Mg), lithium (Li), lithium fluoride (LiF), magnesium (Mg)/copper (Cu), magnesium (Mg)/silver (Ag), sodium (Na)/potassium (K), lithium (Li)/aluminum (Al), lithium (Li)/calcium (Ca)/aluminum (Al), lithium fluoride (LiF)/calcium (Ca)/aluminum (Al), and the like.

The edge cover 32 is formed of an organic resin material, such as a polyimide resin or an acrylic resin, or of a polysiloxane based SOG material, for example.

As illustrated in FIG. 4, the sealing film 45 is provided so as to cover the second electrode 34, includes a first inorganic sealing film 41, an organic sealing film 42, and a second inorganic sealing film 43 layered on the second electrode 34 in that order, and functions to protect the organic EL layer 33 of the organic EL element layer 35 from moisture, oxygen, and the like.

For example, the first inorganic sealing film 41 and the second inorganic sealing film 43 are constituted of an inorganic insulating film, such as a silicon nitride film, a silicon oxide film, a silicon oxynitride film, or the like.

For example, the organic sealing film 42 is constituted of an organic resin material, such as an acrylic resin, an epoxy resin, a silicone resin, a polyurea resin, a parylene resin, a polyimide resin, a polyamide resin, or the like.

Next, an operation of the organic EL display device 100 having the above-described configuration will be described.

### Operation of Peripheral Circuit

As illustrated in FIG. 1, the display control circuit 150 receives an input image signal DIN and a timing signal group (a horizontal synchronization signal, a vertical synchronization signal, and the like) TG transmitted from the outside, and outputs a digital video signal DV, a gate control signal GCTL for controlling the operation of the gate driver 60, an emission driver control signal EMCTL for controlling the operation of the emission driver 70, and a source control signal SCTL for controlling the operation of the source driver 80. Here, the gate control signal GCTL includes a gate start pulse signal, a gate clock signal, and the like. Further, the emission driver control signal EMCTL includes an emission start pulse signal, an emission clock signal, and the like. Further, the source control signal SCTL includes a source start pulse signal, a source clock signal, a latch strobe signal, and the like.

The gate driver 60 is electrically connected to the first scanning signal lines PS(1) to PS(i) and the second scanning signal lines NS(0) to NS(i). Then, based on the gate control signal GCTL output from the display control circuit 150, the gate driver 60 applies the first scanning signal to the first scanning signal lines PS(1) to PS(i), and the second scanning signal to the second scanning signal lines NS(0) to NS(i).

The emission driver 70 is electrically connected to the light emission control lines EM(1) to EM(i). Then, based on the emission driver control signal EMCTL output from the display control circuit 150, the emission driver 70 applies the light emission control signal to the light emission control lines EM(1) to EM(i).

The source driver 80 includes an j-bit shift register, a sampling circuit, a latch circuit, j D/A converters, and the like, which are not illustrated. Here, the shift register includes j cascade-connected registers, and, based on the source clock signal, the shift register sequentially transfers a pulse of the source start pulse signal supplied to a first stage register from an input end to an output end, and a sampling pulse is output from the register of each of stages according to the transfer of the pulse. Then, the sampling circuit stores the digital video signal DV based on the sampling pulse. Then, in accordance with the latch strobe signal, the latch circuit acquires and holds the digital video signal DV for one row stored in the sampling circuit. Then, the D/A converter is provided corresponding to each of the data signal lines D(1) to D(j), converts the digital video signal DV held in the latch circuit to an analog voltage, and applies the converted analog voltage as a data signal (data voltage) to all the data signal lines D(1) to D(j) simultaneously.

As described above, as a result of the data signal being applied to the data signal lines D(1) to D(j), the first scanning signal being applied to the first scanning signal lines PS(1) to PS(i), the second scanning signal being applied to the second scanning signal lines NS(0) to NS(i), and the first light emission control signal being applied to the first light emission control lines EM(1) to EM(i), an image based on the input image signal DIN is displayed in the display region 50.

### Operation of Pixel Circuit of Display Region

Next, the operation of the pixel circuit of the organic EL display device 100 according to the present embodiment will be described using the timing chart in FIG. 6. Note that the operation of the pixel circuit described here is merely an example, and no limitation thereto is intended.

First, before a time t01, the first scanning signal PS(n) is at a high level, and the second scanning signal NS(n−1), the second scanning signal NS(n), and the light emission control signal EM(n) are at a low level. At this time, the power supply control TFT 9e and the light emission control TFT 9f are in an on state, and the second initialization TFT 9g is in an off state. Accordingly, before the time t01, a drive current corresponding to a charging voltage of the capacitor 9h is supplied to the organic EL element 35, and the organic EL element 35 emits light in accordance with the magnitude of the drive current.

At the time t01, as a result of the light emission control signal EM(n) changing from the low level to the high level, the power supply control TFT 9e and the light emission control TFT 9f are in the off state. As a result, the supply of the drive current to the organic EL element 35 is cut off, and the organic EL element 35 is thus in an unlighted state. Further, as a result of the light emission control signal EM(n) changing from the low level to the high level, the second initialization TFT 9g is in the on state. Thus, the voltage of the first electrode 31 of the organic EL element 35 is initialized based on the initialization voltage Vini.

At a time t02, as a result of the second scanning signal NS(n−1) changing from the low level to the high level, the first initialization TFT 9a is in the on state. As a result, a gate voltage of the drive TFT 9d is initialized. In other words, the gate voltage of the drive TFT 9d becomes equal to the initialization voltage Vini.

At a time t03, as a result of the second scanning signal NS(n−1) changing from the high level to the low level, the first initialization TFT 9a is in the off state. Further, at the time t03, the second scanning signal NS(n) changes from the low level to the high level. Thus, the threshold voltage compensation TFT 9b is in the on state.

At a time t04, as a result of the first scanning signal PS(n) changing from the high level to the low level, the write control TFT 9c is in the on state. Here, since the threshold voltage compensation TFT 9b is in the on state at the time t03, when the write control TFT 9c enters the on state at the time t04, the data signal D(m) is input to the second capacitance electrode of the capacitor 9h via the write control TFT 9c, the drive TFT 9d, and the threshold voltage compensation TFT 9b. In this way, the capacitor 9h is charged.

At a time t05, as a result of the first scanning signal PS(n) changing from the low level to the high level, the write control TFT 9c is in the off state.

At a time t06, as a result of the second scanning signal NS(n) changing from the high level to the low level, the threshold voltage compensation TFT 9b is in the off state.

At a time t07, as a result of the light emission control signal EM(n) changing from the high level to the low level, the second initialization TFT 9g is in the off state, and, at the same time, the power supply control TFT 9e and the light emission control TFT 9f are in the on state. In this way, the drive current corresponding to the charging voltage of the capacitor 9h is supplied to the organic EL element 35, and the organic EL element 35 emits the light in accordance with the magnitude of the drive current.

In this way, in the organic EL display device 100, in each of the subpixels P, the organic EL element 35 emits the light at a luminance corresponding to the drive current, and the image display is performed.

Next, a method of manufacturing the organic EL display device 100 according to the present embodiment will be described. Note that the method for manufacturing the organic EL display device 100 includes a TFT layer forming process, an organic EL element layer forming process, and a sealing film forming process.

### TFT Layer Forming Process

First, for example, a silicon oxide film (having a thickness of approximately 100 nm) is formed, for example, by plasma chemical vapor deposition (CVD), on the resin substrate 10 formed on a glass substrate, thus forming the base coat film 11.

Subsequently, an amorphous silicon film (having a thickness of approximately 50 nm) is formed by plasma CVD, for example, on the substrate surface on which the base coat film 11 is formed, the amorphous silicon film is crystallized by laser annealing or the like to form the first semiconductor film 12 made of polysilicon, and then the first semiconductor film 12 is patterned to form the first semiconductor layer 12a.

Subsequently, a silicon oxide film (having a thickness of approximately 100 nm) is formed by plasma CVD, for example, on the substrate surface on which the first semiconductor layer 12a and the like are formed, thus forming the first gate insulating film 13.

Furthermore, after forming the first metal film 14, by forming a molybdenum film or the like (having a thickness of approximately 250 nm) by sputtering, for example, on the substrate surface on which the first gate insulating film 13 is formed, the first metal film 14 is patterned to form the first gate electrode 14a, the fifth gate electrode 14b, and the like.

Subsequently, using the first gate electrode 14a as a mask and doping with impurity ions, a part of the first semiconductor layer 12a is caused to be conductive, and the first conductor region 12aa, the second conductor region 12ab, and the first channel region 12ac are formed on the first semiconductor layer 12a.

Subsequently, a silicon nitride film (having a thickness of approximately 100 nm) is formed by plasma CVD, for example, on the substrate surface on which the first semiconductor layer 12a is formed partially conductive, thus forming the second gate insulating film 15.

Furthermore, after forming the second metal film 16, by forming a molybdenum film or the like (having a thickness of approximately 250 nm) by sputtering, for example, on the substrate surface on which the second gate insulating film 15 is formed, the second metal film 16 is patterned to form the third gate electrode 16a and the like.

Subsequently, the third gate insulating film 17 is formed by sequentially forming a silicon nitride film (having a thickness of approximately 150 nm) and a silicon oxide film (having a thickness of approximately 50 nm), by plasma CVD, for example, on the substrate surface on which the third gate electrode 16a and the like are formed. Furthermore, after forming InGaZnO₄ or the like (having a thickness of approximately 30 nm) by sputtering, to form the second semiconductor film 18 made of the oxide semiconductor, the second semiconductor film 18 is patterned to form the second semiconductor layer 18a and the third semiconductor layer 18b.

Subsequently, a silicon oxide film (having a thickness of approximately 100 nm) is formed by plasma CVD, for example, on the substrate surface on which the second semiconductor layer 18a and the like are formed, thus forming the fourth gate insulating film 19.

Furthermore, after forming the third metal film 20, by forming a molybdenum film or the like (having a thickness of approximately 250 nm) by sputtering, for example, on the substrate surface on which the fourth gate insulating film 19 is formed, the third metal film 20 is patterned to form the second gate electrode 20a, the fourth gate electrode 20b, and the like.

Subsequently, a silicon oxide film (having a thickness of approximately 300 nm) and a silicon nitride film (having a thickness of approximately 150 nm) are sequentially formed by plasma CVD, for example, on the substrate surface on which the second gate electrode 20a and the like are formed, thus forming the interlayer insulating film 21. Note that, by performing heat treatment after forming the interlayer insulating film 21, a part of the second semiconductor layer 18a and a part of the third semiconductor layer 18b are caused to be conductive, and the third conductor region 18aa, the fourth conductor region 18ab, and the second channel region 18ac are formed on the second semiconductor layer 18a, and the fifth conductor region 18ba, the sixth conductor region 18bb, and the third channel region 18bc are formed on the third semiconductor layer 18b.

Subsequently, by patterning the first gate insulating film 13, the second gate insulating film 15, the third gate insulating film 17, the fourth gate insulating film 19, and the interlayer insulating film 21 as appropriate, the contact holes are formed in the substrate surface on which the interlayer insulating film 21 is formed.

Furthermore, after forming the fourth metal film 22 by sequentially forming a titanium film (having a thickness of approximately 50 nm), an aluminum film (having a thickness of approximately 400 nm), a titanium film (having a thickness of approximately 50 nm) and the like by sputtering, for example, on the substrate surface in which the contact holes are formed, the fourth metal film 22 is patterned to form the first terminal electrode, the second terminal electrode, the third terminal electrode, the fourth terminal electrode, the fifth terminal electrode, and the sixth terminal electrode.

Finally, after applying a polyimide-based photosensitive resin film (having a thickness of about 2 m) to the substrate surface on which the first terminal electrode and the like are formed, by spin coating or slit coating, for example, pre-baking, exposing, developing, and post-baking are performed on the applied film to form the flattening film 23.

As described above, the TFT layer 30 can be formed.

### Organic EL Element Layer Forming Process

The organic EL element layer 40 is formed by forming, using a known method, the first electrode 31, the edge cover 32, the organic EL layer 33, and the second electrode 34 on the flattening film 23 of the TFT layer 30 that has been formed in the TFT layer forming process.

### Sealing Film Forming Process

First, the first inorganic sealing film 41 is formed, using a mask, for example, by forming an inorganic insulating film, such as a silicon nitride film, a silicon oxide film, a silicon oxynitride film, or the like, by plasma CVD, on the substrate surface on which the organic EL element layer 40 formed in the above-described organic EL element layer forming process is formed.

Subsequently, on the substrate surface on which the first inorganic sealing film 41 is formed, a film made of an organic resin material such as acrylic resin is formed by an ink-jet method, for example, to form the organic sealing film 42.

Subsequently, using a mask, an inorganic insulating film such as a silicon nitride film, a silicon oxide film, or a silicon oxynitride film is formed by plasma CVD, for example, on the substrate surface on which the organic sealing film 42 is formed, to form the second inorganic sealing film 43, thus forming the sealing film 45.

Finally, after a protective sheet (not illustrated) is adhered to the substrate surface on which the sealing film 45 is formed, the glass substrate is peeled off from the lower face of the resin substrate 10 by irradiation with laser light from the glass substrate side of the resin substrate 10, and then a protective sheet (not illustrated) is adhered to the lower face of the resin substrate 10 from which the glass substrate has been peeled.

The organic EL display device 100 according to the present embodiment can be manufactured as described above.

As described above, according to the organic EL display device 100 according to the present embodiment, the third TFT 9C constituting the second initialization TFT 9g for resetting the electric charge accumulated in the first electrode 31 includes the fourth gate electrode 20b provided, via the fourth gate insulating film 19, on the third semiconductor layer 18b formed by the second semiconductor film 18 made of the oxide semiconductor, and the fifth gate electrode 14b provided, via the second gate insulating film 15 and the third gate insulating film 17, on the resin substrate 10 side of the third semiconductor layer 18b. On the other hand, the second TFT 9B constituting the first initialization TFT 9a for resetting the electric charge accumulated in the capacitor 9h, and the threshold voltage compensation TFT 9b includes the second gate electrode 20a provided, via the fourth gate insulating film 19, on the second semiconductor layer 18a formed by the second semiconductor film 18, and the third gate electrode 16a provided, via the third gate insulating film 17, on the resin substrate 10 side of the second semiconductor layer 18a. Thus, in the third TFT 9C, the inorganic insulating film between the third semiconductor layer 18b and the fifth gate electrode 14b is thicker than the inorganic insulating film between the second semiconductor layer 18a and the third gate electrode 16a in the second TFT 9B, by an amount corresponding to the thickness of the second gate insulating film 15. Here, since the second initialization TFT 9g does not need to be reset at a high speed compared to the first initialization TFT 9a, by causing the inorganic insulating film between the third semiconductor layer 18b and the fifth gate electrode 14b to be thicker, the drive capability of the second initialization TFT 9g (the third TFT 9C) is intentionally reduced. As a result, it is possible to suppress fluctuations in a potential of the initialization voltage Vini, and it is thus possible to stabilize a reset potential of the first initialization TFT 9a. Further, since the light emission control line EM disposed in the vicinity of the second initialization TFT 9g (the third TFT 9C) can have a dual-layer structure of the wiring line layer formed by the first metal film 14 and the wiring line layer formed by the third metal film 20, the electric capacitance of the light emission control line EM can be reduced. As a result, the drive capability of the emission driver 70 that applies the light emission control signal to the light emission control line EM can be reduced, and it is thus possible to realize frame narrowing to narrow the width of the frame region. Thus, it is possible to form the second TFT 9B and the third TFT 9C having the double gate structure using the oxide semiconductor with as simple a configuration as possible.

Further, according to the organic EL display device 100 according to the present embodiment, in the second TFT 9B and the third TFT 9C provided with the second semiconductor layer 18a and the third semiconductor layer 18b formed by the second semiconductor film 18 made of the oxide semiconductor, since the third gate electrode 16a and the fifth gate electrode 14b are respectively provided as a back gate, the second channel region 18ac of the second semiconductor layer 18a and the third channel region 18bc of the third semiconductor layer 18b can be shielded from light.

Further, according to the organic EL display device 100 according to the present embodiment, since the second TFT 9B and the third TFT 9C have the double gate structure provided with the second semiconductor layer 18a and the third semiconductor layer 18b formed by the second semiconductor film 18 made of the oxide semiconductor, the on/off characteristics of the second TFT 9B and the third TFT 9C can be improved.

Further, according to the organic EL display device 100 according to the present embodiment, since the base coat film 11 made of the inorganic insulating film is provided between the resin substrate 10 and the first semiconductor layer 12a, film peeling of the first semiconductor layer 12a can be suppressed.

### Other Embodiments

Although the organic EL layer having a five-layer structure including the hole injection layer, the hole transport layer, the light-emitting layer, the electron transport layer, and the electron injection layer has been exemplified in each of the embodiments described above, the organic EL layer may have a three-layer structure including a hole injection-cum-transport layer, a light-emitting layer, and an electron transport-cum-injection layer, for example.

In each of the embodiments described above, the organic EL display device including the first electrode as an anode electrode and the second electrode as a cathode electrode is exemplified. The disclosure can also be applied to an organic EL display device in which the layered structure of the organic EL layer is reversed with the first electrode being a cathode electrode and the second electrode being an anode electrode.

In each of the embodiments described above, the organic EL display device is exemplified as a display device. The disclosure can also be applied to a display device including a plurality of light-emitting elements driven by an electric current, and can be applied, for example, to a display device including quantum dot light-emitting diodes (QLEDs), which are a light-emitting element using a quantum dot-containing layer.

### INDUSTRIAL APPLICABILITY

As described above, the disclosure is useful for a flexible display device.

1. A display device comprising:
a base substrate; and
a thin film transistor layer which is provided on the base substrate and in which a first semiconductor film made of polysilicon, a first inorganic insulating film, a first metal film, a second inorganic insulating film, a second metal film, a third inorganic insulating film, a second semiconductor film made of an oxide semiconductor, a fourth inorganic insulating film, and a third metal film are layered in this order, the thin film transistor layer including, for each of subpixels constituting a display region, a first thin film transistor including a first semiconductor layer formed by the first semiconductor film, a second thin film transistor including a second semiconductor layer formed by the second semiconductor film, and a third thin film transistor including a third semiconductor layer formed by the second semiconductor film,
wherein the first thin film transistor includes
the first semiconductor layer including a first conductor region and a second conductor region defined to be separated from each other, and also including a first channel region defined between the first conductor region and the second conductor region, and
a first gate electrode provided overlapping the first channel region, on the first semiconductor layer, via the first inorganic insulating film, the first gate electrode being formed by the first metal film,
the second thin film transistor includes
the second semiconductor layer including a third conductor region and a fourth conductor region defined to be separated from each other, and also including a second channel region defined between the third conductor region and the fourth conductor region,
a second gate electrode provided overlapping the second channel region, on the second semiconductor layer, via the fourth inorganic insulating film, the second gate electrode being formed by the third metal film, and
a third gate electrode provided overlapping the second channel region, on a side of the base substrate of the second semiconductor layer, via the third inorganic insulating film, the third gate electrode being formed by the second metal film, and
the third thin film transistor includes
the third semiconductor layer including a fifth conductor region and a sixth conductor region defined to be separated from each other, and also including a third channel region defined between the fifth conductor region and the sixth conductor region,
a fourth gate electrode provided overlapping the third channel region, on the third semiconductor layer, via the fourth inorganic insulating film, the fourth gate electrode being formed by the third metal film, and
a fifth gate electrode provided overlapping the third channel region, on a side of the base substrate of the third semiconductor layer, via the second inorganic insulating film and the third inorganic insulating film, the fifth gate electrode being formed by the first metal film.

2. The display device according to claim 1,
wherein the first thin film transistor is provided to constitute a write control thin film transistor, a drive thin film transistor, a power supply control thin film transistor, or a light emission control thin film transistor,
the second thin film transistor is provided to constitute a first initialization thin film transistor configured to reset an electric charge accumulated in a capacitor, or to constitute a threshold voltage compensation thin film transistor, and
the third thin film transistor is provided to constitute a second initialization thin film transistor configured to reset an electric charge accumulated in an anode electrode.

3. The display device according to claim 1,
wherein a plurality of light emission control lines extending in parallel with each other are provided in the display region, and
each of the plurality of light emission control lines is formed by the first metal film and the third metal film.

4. The display device according to claim 1,
wherein the base substrate is a resin substrate,
a base coat film is provided on the resin substrate, and
the first semiconductor film is provided on the base coat film.

5. The display device according to claim 1, further comprising:
a light-emitting element layer provided on the thin film transistor layer and provided with a plurality of light-emitting elements arrayed; and
a sealing film provided covering each of the plurality of light-emitting element layers.

6. The display device according to claim 5,
wherein each of the plurality of light-emitting elements is an organic electroluminescence element.
